(19) United States
(12) Patent Application Publication
(10) Pub. No.: US 2022/0398364 A1
(43) Pub. Date: Dec. 15, 2022

(54) METHOD FOR ANALYZING REACHABILITY OF PETRI NET

(71) Applicant: Tsung Hsien Yu, Taipei (TW)

(72) Inventor: Tsung Hsien Yu, Taipei (TW)

(21) Appl. No.: 17/831,429

(22) Filed: Jun. 2, 2022

Related U.S. Application Data
(60) Provisional application No. 63/196,356, filed on Jun. 3, 2021.

(51) Int. Cl. G06F 30/22; G06N 5/02; G05B 17/02

(52) U.S. Cl. CPC G06F 30/22; G06N 5/02; G05B 17/02

(57) ABSTRACT

A method for analyzing reachability of a Petri net and deriving the control-related state of the PN extended from the kth variant closed-form formula (CFF) system for numbers, comprising by proving that the first system Gen-Right(k, gen) and the second system Gen_Left(k, k−gen) are topological inverse networks of Gen-Left(k, gen), the first system and the second system An invertible one-to-one mapping between; wherein the first series Gen-Right(k, gen) and Gen-Left(k, k−gen) have the same closed-form formula, and by putting Gen-Left(k, gen) in the verified closed-form formula The parameter gen can be obtained by replacing it with k−gen, and its corresponding reachability state can be directly obtained through a reversible one-to-one mapping.

### CROSS REFERENCE TO RELATED APPLICATION

The present application claims the benefit of U.S. Provisional Application Ser. No. 63/196,356, filed on Jun. 3, 2021, which is hereby incorporated by reference in its entirety.

### FIELD OF THE INVENTION

The present invention relates to an efficient knowledge-based methodology, Topological Reverse Mirroring (TRM) for analyzing reachability and deriving the number closed-form formulas (CFF) of the number of Control-Related states (Reachable, live, forbidden, deadlock, livelock, non-reachable) (CRSs) for PNs. The present invention also provides the CFF of the number of CRSs for double deficient k-th order system with one non-sharing resource, which is the core S³PR (a system of simple sequential process with resources), as the basic model for applying TRM to derive CFF for more complicated PNs to providing real-time reachability information based on current state for the decision-making of system control applications.

### BACKGROUND

Petri nets (PNs) have been widely applied for modeling and analyzing concurrent systems, such as resource allocation systems (RAS) (or flexible manufacturing systems, FMS). Reachability analysis can be used to verify system properties of boundedness, liveness, reversibility, and so on.

However, a persistent problem of using PNs to model very large systems is the large number of states generated (also known as the state explosion problem). The complexity of the reachability problem of PNs is EXPSPACE-hard and also is NP-complete. The time to compute the reachable states only (not including the live, forbidden and deadlock states) of a variant k-net system with k=9, μ=4 and gen=8 in a PC of Intel® Core™ i5 CPU 650 @3.20 Ghz 4.00 GB RAM environment is over 5 minutes by INA tools.

Even mixed integer programming (MIP) method applied for system-control applications in PNs, the non-deterministic polynomial-time hard (NP-hard) characteristic of the MIP still limits the size of real-time systems modeled in real application.

Chao et al. have constructed CFS for k-th order/k-net system with a non-sharing resource r* in different locations (referenced to Chao & Yu, 2013; Chao & Yu, 2015; Chao & Yu 2016; Chao, Yu, & Chen, 2014; Chao, Yu, & Lin, 2014; Chao, Yu, & Liou, 2014; Chao, Yu, &Wu, 2014; Chao et al. 2016) by siphon analysis method, respectively. The reachability information of PNs become a new type of real-time information for system-control application but limited in modeling by variant k-th order/k-net system.

Due to the fact that the number of CRSs of a very large PN can be derived real-time by CFS, some new system-control concepts are proposed based on such new type real-time information as shown followings.

First, one can apply the future deadlock ratio (the number of deadlock states/the number of reachable states) of the (potential) forbidden sub-states, which can be derived real-time by CFS, as the indicator for dynamically launching resources (controllers) allocation for a deadlock avoidance/prevention policy (Chao and Yu, 2015a; 2016).

Second, Yu (2016a) proposed that one can dynamically allocate a dummy non-sharing waiting resource (denoted by deadlock thread holder, DTH) based on which location DTH allocated will increase maximum reachability to avoid deadlock, where the location can be calculated real-time by CFS.

Third, Yu (2017) showed that lower modified deficient reachability ratio (DRO) (the number of reachable states under deficient initial tokens/the number of reachable states) has better margin effect of reachability. Accordingly, one can set up a dynamic initial token allocation mechanism for a multi-independent insufficient k-th order systems according to which system has the lowest DRO value.

The main problem of new system-control concepts listed above is that one needs real-time reachability information based on current state to calculate the essential indicators for the decision-making of allocating/deallocating resources or processes.

Another problem listed above are that one has got as many independently analyzing whole net structure efforts as different net structures there are. Furthermore, the complicated proof procedures by analyzing whole net structure are barriers to comprehend the whole methodology in reachability analysis.

### SUMMARY OF THE DISCLOSURE

The present invention relates to an efficient knowledge-based methodology. Regarding the present invention, Topological Reverse Mirroring (TRM) is utilized for analyzing reachability and deriving the number closed-form formulas (CFF) of the number of Control-Related states (Reachable, live, forbidden, deadlock, livelock, non-reachable) (CRSs) for Petri Nets (PNs). The present invention also provides the CFF of the number of CRSs for Double Deficient k-th order system with one non-sharing resource, which is the core S³PR (a system of simple sequential process with resources), as the basic model for applying TRM to derive CFF for more complicated PNs to providing real-time reachability information based on current state for the decision-making of system control applications.

An object of the present invention is to provide Topological Reverse Mirroring (TRM) a knowledge-based methodology, which is using the concept of proof by modeling instead of by analyzing the whole net structure, to reduce the efforts of analyzing reachability listed above.

Another object of the present invention is to provide the CFF for Variant Double Deficient k-th order system with one non-sharing resource as basic model for using TRM to derive CFF for more complicated PNs.

Therefore, a reachability analysis method for a Petri Net (PN) for analyzing reachability and deriving the control-related state of the PN extended from the kth variant closed-form formula (CFF) system for numbers is provided. The method comprises: by proving that the first system Gen-Right(k, gen) and the second system Gen_Left(k, k−gen) are topological inverse networks of Gen-Left(k, gen), the first system and the second system An invertible one-to-one mapping between; wherein the first series Gen-Right(k, gen) and Gen-Left(k, k−gen) have the same closed-form formula, and by putting Gen-Left(k, gen) in the verified closed-form formula The parameter gen can be obtained by replacing it with k−gen, and its corresponding reachability state can be directly obtained through a reversible one-to-one mapping.

Preferably, the method is based on knowledge-based use of the verified network accessibility and closure solution information to change parameter values such as itineraries, non-shared resources and multi-scepter shared resources locations, and directly obtain the new network, the network architecture has a reversible one-to-one mapping of the reachability and closure solution information of the new network architecture, the method is referred to here as Topological Reverse Mirroring (TRM).

Preferably, the topological inverse mirror system is used to analyze reachability and derive a closed-form formula to control the number of control-related states.

Preferably, the control-related states are reachable, active, prohibited, deadlocked, livelocked, and unreachable.

Preferably, the method further includes providing the CFF of the number of CRSs of the double-deficient k-order system of non-shared resources.

Preferably, the method further includes using embedded filter coefficients (EFC) in front of the CFF as a necessary condition for each of the α and β of the CRS.

Preferably, the necessary conditions for the EFC of the reachable state are α≥0 and β≥0; where min(max(min(α, β, 0)+1, 0), 1)) is used as the embedded filter coefficient (EFC) to exclude possibilities (α<0 or β<0).

Preferably, the necessary conditions for the EFC of the active state are α>0 and β>0, but excluding the conditions of α=0 and β=0; where, using (min(max(min(α, β, 0)+1, 0), 1)) (min(max(max(α, 0), max(β, 0)), 1)) as EFC.

Preferably, the basic condition of the EFC of the dead state is (α=β=0) union (α>0 and β>0); where, use 1−(min(max(max(α, 0), max(β, 0)), 1)) for the special condition of (α=β=0); max(min(α, β, 1), 0) as (α>0 and β>0) EFC of CFF under condition.

Preferably, the CFF of the number of CRSs of the non-shared resource double-deficient k-order system is used as the basic model for deriving the CFF of more complex PNs by applying the TRM, and provides decision-making based on the current state of the real-time reachability information system control application.

### BRIEF DESCRIPTION OF THE DRAWINGS

One or more embodiments are illustrated by way of example, and not by limitation, in the figures of the accompanying drawings, wherein elements are having the same reference numeral designations represent like elements throughout. The drawings are not to scale, unless otherwise disclosed.

FIG. 1 is a k-th order system, where k=3;

FIG. 2 is a Gen-Left(k, gen) system where k=3 and gen=1;

FIG. 3(a) is a Gen-Left(k, gen) system where k=3 and gen=2;

FIG. 3(b) is the reverse net of a Gen-Left(k, gen) system where k=3 and gen=1;

FIG. 4 is the mapping relation of Gen-Left(k, gen), rev(Gen-Left(k, gen)) and Gen-Right(k, gen);

FIG. 5 is an ordinary NNS k-th order system: composed by Deficient k-th order system and NNS;

FIG. 6 is a double-NNS system; and

FIG. 7 is the mapping relation of k_{1(μ-1)}(1⁺, 1) and k_{1(μ-1)}(1⁺, k−1)-th order system where k=4.

### DETAILED DESCRIPTION

Unless defined otherwise, all technical and scientific terms used herein have the same meanings as commonly understood by one of skill in the art to which this disclosure belongs. It will be further understood that terms; such as those defined in commonly used dictionaries, should be interpreted as having a meaning that is consistent with their meaning in the context of the relevant art and the present disclosure, and will not be interpreted in an idealized or overly formal sense unless expressly so defined herein.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

To solve the problems listed above, the present invention reports Topological Reverse Mirroring (TRM), a knowledge-based methodology, to accelerate reachability analysis and the construction of CFF for more complicated PNs without whole net structure analysis; and provides the CFF of the number of CRSs for Double Deficient k-th order system with one non-sharing resource as the basic model for applying TRM to derive CFF for more complicated PNs to providing real-time reachability information based on current state for the decision-making of system control applications.

Comparing to presently analyzing whole net structure method, topological reverse mirroring’ (TRM) is a new knowledge-based methodology for more efficiently analyzing reachability and deriving the closed-form formulas (CFF) of the number of Control-Related states for PNs extended from variant k-th order systems.

According to variant k-th order systems, TRM is constructed by proving that both Gen-Right(k, gen) and Gen_Left(k, k−gen) are the topological reverse nets of Gen-Left(k, gen) such that there is a reversible one-to-one mapping (Mirroring) between these two systems. Thus, CFF for Gen-Right(k, gen) and Gen-Left(k, k−gen) have same CFF, which can be immediately derived by replacing the parameter ‘gen’ by ‘k−gen’ in validated CFF for Gen-Left(k, gen). The CFF for variant double deficient k-th order system is reported as the basic system to extend analyzing reachability and deriving the CFF for more topological reverse mirroring. Also, the present invention provides real-time reachability information based on current state. The shown applications of TRM include the reachability analyzing for systems with non-sharing sub-net; double deficient tokens; multi-non-sharing/multi-tokens resources; and multi-processes extended from k-th order system. The present invention reports the core methodology to accelerate furthering emerging system-control applications for more complicated PNs based on the real-time information derived by their CFF.

A Petri net is a 4-tuple N=(P, T, F, W), where P is the set of places, T is the set of transitions, F⊆(P×T)∪(T×P) is called flow relation of the net, represented by arcs with arrows from places to transitions or vice versa, and W: F→Z (the set of non-negative integers) is a mapping that assigns a weight to an arc. M₀: P→Z is the initial marking assigned to each place p∈P, M₀(p) token, and (N, M₀) is called a marked net or a net system. The set of input (resp. output) transitions of a place p is denoted by ^{•}p (resp. p^{•}).

Similarly, the set of input (resp. output) places of a transition t is denoted by ^{•}t (resp. t^{•}). It is called a Marked Graph (MG) if ∀p∈^{⋅}P, |p^{⋅}|=|^{⋅}p|=1. An elementary directed path Γ in N is a graphical object containing a sequence of nodes such that there is an arc between each two successive nodes in the sequence with the notation: Γ=[n₁ n₂ . . . nₖ], k≥1, such that nᵢ≠nⱼ for i≠j is the reverse net of N obtained by reversing the direction of all arcs in N with the initial marking unchanged. A is the incidence matrix of a net with m places and n transitions: A=[aᵢⱼ]; a matrix of integers and its typical entry is given by aᵢⱼ=aᵢⱼ⁺−aᵢⱼ⁻ where aᵢⱼ⁻=W(i, j) is the weight of the arc from transition i to its output place j, and aᵢⱼ⁺=W(j, i) is the weight of the arc to transition i from its input place j. A^{r}=−A where A^{r} is the incidence matrix of the reverse net N^{r} of N. Given a marking M, a transition t is enabled if ∀p∈^{⋅}t, M(p)≥W(p, t), and this is denoted by M[t>. Firing an enabled transition t results in a new marking M₁, which is obtained by removing W(p, t) tokens from each place p∈^{⋅}t and placing W(t, p′) tokens in each place p′∈t^{⋅}, moving the system state from M₀ to M₁.

Repeating the foregoing process, it reaches M′ by firing a sequence σ=t₁t₂ . . . tₖ of transitions. M′ is said to be reachable from M0; i.e., M₀[σ>M′. R(N, M₀) is the set of markings reachable from M₀. A forbidden (resp. live) marking or state is one that is (resp. is not) a—or necessarily evolves into—a deadlock marking. For a Petri net (N, M₀), a non-empty subset S (resp. τ) of places is called a siphon (resp. trap) if ^{•}S⊆S^{•}(resp. τ^{•}⊆^{•}τ), i.e., every transition having an output (resp. input) place in S has an input (resp. output) place in S (resp. τ). A siphon is a set of places where tokens can continuously flow out so that M₀(S)=Σ_{p∈S}M₀ (p)=0, S is called an empty siphon or unmarked siphon at M₀; all output transitions of S are permanently dead.

Several definitions are introduced in the following paragraphs.

Definition 1

(J. Ezpeleta et al. 1995): A simple sequential process (S²P) is a net N=(P∪{p⁰}, T, F) where: P≠Ø, p⁰∉P (p⁰ is called the process idle or initial or final operation place); 2) N is strongly connected state machine and 3) every circuit of N contains the place p⁰.

Transitions in p^{0⋅} and ^{⋅}p⁰ are called source and sink transitions respectively.

Definition 2

(J. Ezpeleta et al. 1995): A simple sequential process with resources (S²PR), also called a working process (WP), is a net N=(P∪{p⁰}∪P_{R}, T, F) so that 1) the subnet generated by X=P∪{p⁰}∪T is an S²P; 2) P_{R}≠Ø and P∪{p⁰}∩P_{R}=Ø; 3)∀p∈P, ∀t∈^{⋅}p, ∀t′Ep^{⋅}, ∃rₚ∈P_{R}, t∩P_{R}=t′^{•}ωP_{R}={rₚ}; 4) The two following statements are verified: ∀r∈P_{R}, a) ^{⋅⋅}r∩P=r^{⋅⋅}∩P≠Ø; b) ^{⋅}r∩r^{⋅}=Ø. 5) ^{⋅⋅}(p⁰)∩P_{R}=(p0)^{⋅⋅}∩P_{R}=Ø. ∀p∈P, p is called an operation place. ∀r∈P_{R}, r is called a resource place. H(r)=^{⋅⋅}r∩P denotes the set of holders of r (operation places that use r). Any resource r is associated with a minimal P-invariant whose support is denoted by ρ(r)={r}∪H(r).

Definition 3

(J. Ezpeleta et al. 1995): A system of S²PR (S³PR) is defined recursively as follows: 1) An S²PR is defined as an S³PR; 2) Let Ni=(Pᵢ∪Pᵢ⁰∪P_{Ri}, Tᵢ, i∈{1,2} be two S³PR so that)) (P₁∪P₁⁰)∩(P₂∪P₂⁰)=Ø. PR₁∩PR₂=P_{C}(≠Ø) and T₁∩T₂=Ø. The net N=(P∪P⁰∪P_{R}, T, F) resulting from the composition of N₁ and N₂ via P_{C} (denoted by N₁ o N₂) defined as follows: 1) P=P₁∪P₂; 2) P⁰=P₁⁰∪P₂⁰; 3) P_{R}=P_{R1}∪P_{R2}; 4) T=T₁∪T₂ and 5) Γ=F₁∪F₂ is also an S³PR.

Definition 4

A variant k-th order system is a subclass of S³PR with k resource places r₁, r₂, . . . , rₖ shared between two processes N₁ and N₂ and one non-sharing resource place r′_{gen} (=r*) used by an operation place p* in N₁ or N₂.
1. M₀(r′_{gen})=1 and ∀r∈P_{R}, M₀(r)=1.
2. N₁ (resp. N₂) uses r₁, r₂, . . . , rₖ (resp. rₖ, rₖ₋₁, . . . r₂, r₁) in that order.
3. When p* in N₁ (resp. N₂) M₀(p₀)=k+1, M₀(p′₀)=k (resp. M₀(p₀)=k, M₀(p′₀)=k+1), where p₀ and p′₀ are the idle places in processes N₁ and N₂, respectively.
4. Holder places of rⱼ in N₁ and N₂ are denoted as pⱼ and p′ⱼ respectively.
5. The compound circuit containing rᵢ, rᵢ₊₁, . . . rⱼ₋₁, rj is called the (rᵢ-rⱼ)-region.
6. The position of r′_{gen} is located between r_{gen} and r_{gen+1}. If r′_{gen} does not exist, then it is called a k-th order system; when M₀(p₀)<k, then it is called a Deficient k-th order system; when both M₀(p₀)<k and M₀(p′₀)<k, then it is called a Double Deficient k-th order system.
7. There are 3 possibilities for the token initially at rᵢ to sit at: pᵢ(N₁), p′ᵢ(N₂), and rᵢ. The corresponding token or rᵢ state is denoted by 1, −1 and 0, respectively.
8. x[y] means r_{gen} is at x state (x=1, 0, −1) and r′_{gen} is at y state (y=1, 0, −1), where gen is the location of non-sharing resource being used by an operation place p*, 1≤gen≤k−1. The system is denoted as a Gen-Left(k, gen) system when p* in N₁; a Gen-Right(k, gen) system when p* in N₂. Unless otherwise listed parameters, Gen-Left is the abbreviation of Gen-Left(k, gen); Gen-Right is the abbreviation of Gen-Right(k, gen).
9. The union of Gen-Left and Gen-Right is denoted as a Gen-One system.

Definition 5

A generalized k-th order system (k-net) (Chao, 2016; Chao & Yu, 2014; 2016) is a subclass of S³PR with k resource places r₁, r₂, . . . , rₖ shared between α+ processes N₁⁺, N₂⁺, . . . , Nα⁺ and β⁻ processes, N₁⁻, N₂⁻, . . . , N_{β}⁻ (denoted as k G th-order system). M(r)=M(r)= . . . =M (r)=1. Nᵢ⁺(respectively Nⱼ⁻) uses r₁, r₂, . . . , rₖ (resp. rₖ, rₖ₋₁, . . . r₂, r₁) in that order, i=1, 2, . . . , α(resp. j=1, 2, . . . , β). Each of Nᵢ⁺ and Nⱼ⁻ is an elementary circuit. When there is exactly one+ process and one− process, a generalized k-th order system becomes a k-th one (a k G-th order system is a k-th order system). P⁺ (respectively P⁻) is the set of operation places in + processes (respectively− processes). H(r)⁺ (respectively H(r)⁻) is the set of holder places of r that are in P⁺ (respectively P⁻). Let a generalized k-th order system with a non-sharing resource in gen location of Nᵢ process be denoted as a kαβ(i, gen)-th order system.

Definition 6

The equivalent N^{e}=(P^{e}∪P^{e}_{R}, F^{e}) of a net N=(P∪P_{R}∪P_{NR}, T, F) (P_{NR} is the set of non-sharing places) is defined as
1. P^{e}_{R}=P_{R}\P_{NR};
2. P^{e}=P\∪_{r∈PNR}H(r);
3. T^{e}=T\∪_{r∈PNR}r^{⋅};
4. F^{e}=(F∪_{r∈PNR}(^{⋅}r,r^{⋅⋅})∪(^{⋅}(r^{⋅}),^{⋅}r)\∪_{r∈PNR} [(H(r), H(r)^{⋅})∪(^{⋅}H(r), H(r))∪(^{⋅}r,r)∪(r,r^{⋅}) ∪(r^{⋅},r^{⋅⋅})∪(^{⋅}(r^{⋅}),r^{⋅})].

Definition 7

(Chao, 2014): s=(x₁ x₂ . . . xₖ), xᵢ=1, 0 or −1, i=1 to k, is a state for a k-th order system N, xᵢ is the token at rᵢ to sit at: pᵢ(N₁), rᵢ or p′ᵢ(N₂) respectively. (xᵢ xᵢ₊₁ . . . x_{q}), k≥i≥1, k≥q≥i≥1 (embedded in s) is a sub-state of s.

Theoretical Framework for Constructing CFS for PNs

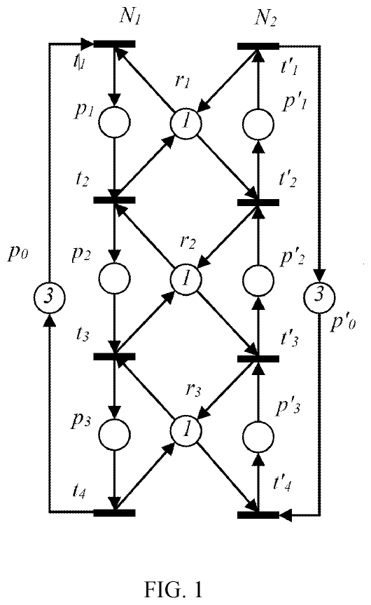

According to Definition 4, examples of the subset of Gen-One k-th order system are shown in FIGS. 1, 2, and 3(a).

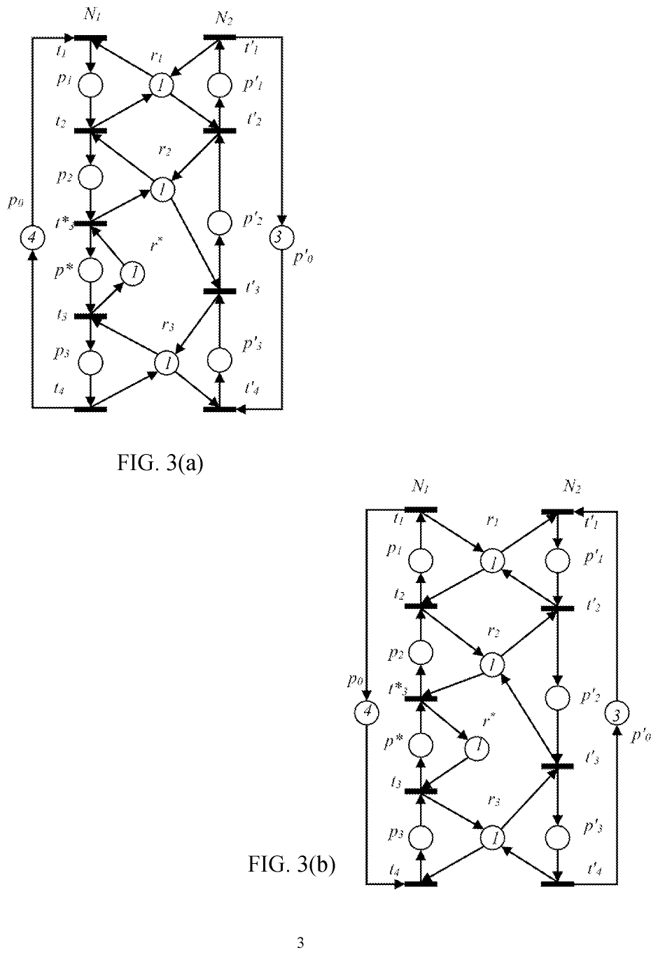

Let rev(N) be the reverse net of a PN N (e.g., FIGS. 3(a) and 3(b)). According to the concept of a Complete reachability graph, Chao (2014) split the reachability graph of a PN N into reachable (from the initial state), live (reachable to the initial state), forbidden (reachable to the livelock (Chao & Yu, 2017) or deadlock states only), livelock (Chao & Yu, 2017) (reachable to the livelock state only), deadlock (reachable to no state), non-reachable (from the initial state) and non-reachable+empty-siphon states (both non-reachable states in a N and the rev(N)).

According to Definitions 4 and 7, the present invention presents the notation of state and sub-state by the viewpoint of the distribution of tokens between “resources” instead of by the viewpoint of the “places” applied by INA tools. For example, when p₁, p₂ and p′₃ contain one token in FIG. 1, the state is denoted by (1 1 −1). For example, a state containing a sub-state (1 −1) in a k-th order system must be a forbidden state due to empty siphon; containing a sub-state (−1 1) must be a non-reachable state; a sub-state (1[y] −1) contains a non-sharing resource with y sub-state. According to this notation of a state, a non-sharing resource allocated (resp. deallocated) in a sub-state (1 −1) (resp. 1[0] −1) can be denoted by (1[0] −1) (resp. (1 −1)).

In addition, Chao (2014) showed that (−1 0 1), (−1 1 x) and (x −1 1) [resp. (1 0 −1), (1 −1 x) and (x 1 −1)] where x=−1, 0 or 1 are three basic kinds of non-reachable (resp. unmarked siphon) states in k-th order system where k=3. Extending to a large system, a non-reachable state contains the sub-states pattern (−1 x x x 1) where x=1, 0, −1; a sub-state of (1 x x x −1) (x=1, 0, −1) corresponds to a forbidden or a non-reachable state; and a forbidden state finally reaches to a deadlock state that has the state pattern: (1₁ 1₂ . . . 1ₘ −1ₘ₊₁ −1ₘ₊₂ . . . −1ₖ), 1≤m<k.

Further, Chao (2014) proved that any forbidden state in an N is non-reachable in rev(N); any non-reachable states in a N is a forbidden one or a non-reachable one in rev(N). Chao et al. (2016) enhanced this theoretical framework by proving that a reverse state of a live state in a N is also a live state in the rev(N) such that both of N and rev(N) have same number of live states.

The Effects of a Non-Sharing Resource in Variant k-th Order System

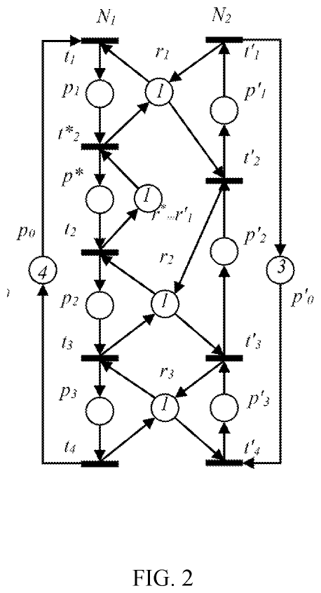

By the definition of the equivalent (Definition 6), k-th order system (e.g. FIG. 1) is the equivalent of the net Gen-One (e.g. FIGS. 2 and 3(a)), since the net in FIG. 1 is exactly the same as the net in FIGS. 2 and 3(a) except for one non-sharing resource place r*.

Let N be Gen-One k-th order system (e.g. Gen-Left or Gen-Right), Ne be the corresponding k-th order system, y=1 in Gen-Left, y=−1 in Gen-Right, the generalized forbidden and non-reachable state pattern in Gen-one are shown as following:
1. The patterns of forbidden states including the non-sharing resource in N are the states that contain or will contain sub-state (1 0[y] −1) and (1[y] −1); the non-reachable states part contains or will contain sub-state (−1[y] 1) and (−1 0[y] 1).
2. A sub-state of (−1 x . . . x[y] x . . . 1) (x=1, 0, −1) is a non-reachable state in N.
3. A sub-state of (1 x . . . x[y] x . . . −1) (x=1, 0, −1) is a forbidden or a non-reachable state in N.

The followings list the effects of increasing a non-sharing resource in k-th order system based on the viewpoint of Gen-Left (Chao and Yu, 2016) and then extending the viewpoint to Gen-one.
1. Let M^{e} be reachable (resp. live) in N^{e}, since both M*=M^{e}+r* and M′=M^{e}+p* are reachable (resp. live) in N, and the number of reachable (resp. live) states is greater than 2R(k) (resp. 2L(k)).
2. The phenomenon of increasing “the additional restricted reachable (resp. live) states derived from non-reachable (resp. non-live, including non-reachable and forbidden) states of the equivalent caused by a non-sharing resource”, ARRS, (resp. ARLS) occurs when one process waits for the work flow of the other process in the holder of the one existing non-sharing resource. In this situation the current state is a non-reachable (resp. non-live) marking of N^{e} but a reachable (resp. maybe live) marking of Gen-one. The states pattern of ARRS in Gen-Left is s=(x₁ . . . −1ᵢxᵢ₊₁ . . . x_{gen} . . . xⱼ₊₁ xⱼ₊₂ . . . xₖ) where xₘ=0 or −1, i+1≤m≤gen and j+1≤m≤k; xₘ=0, gen+1≤m≤j−1; (x₁ . . . xᵢ₋₁) is a reachable states pattern of (i−1)-th order system, because the process can wait in only one existing non-sharing resource for the other process work flow.

1. Topological Reverse Mirroring (TRM), a Knowledge-Based Methodology:

Based on variant k-th order system, Topological Reverse Mirroring (TRM) methodology is constructed by proving Theorem 1.1, Lemma 1.1 and Corollary 1.1 as shown below:

Theorem 1.1: Gen-Right(k, gen), rev(Gen-Left(k, gen)), and Gen-Left(k, k−gen) have the same topological net structure.

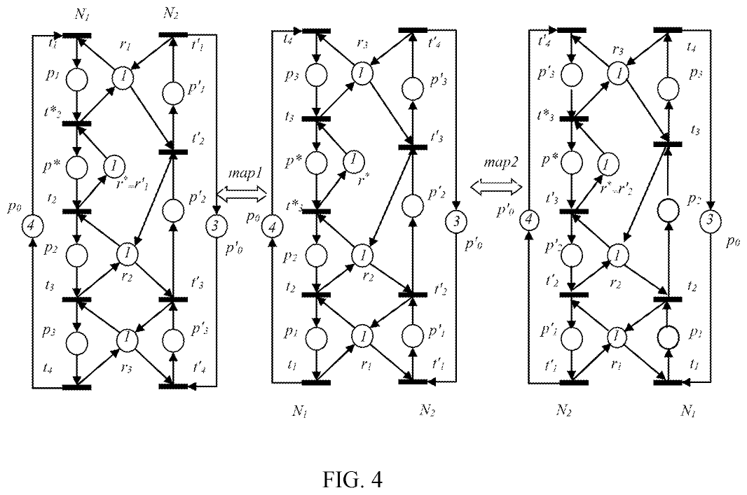

FIG. 4 shows two mapping functions map1 and map2. map1 is the mapping relation from Gen-Left(k, k−gen) where k=3 and gen=k−1 to the inverted net structure of rev(Gen-Left(k, gen)) such that map1 (Gen-Left(k, k−gen))=rev(Gen-Left(k, gen)). map2 is the mapping relation from rev(Gen-Left(k, gen)) to the inverted and left and right rotation net structure of Gen-Right(k, gen) such that map2(rev(Gen-Left(k, gen)))=Gen-Right(k, gen). According to compound function map3=map2∘map1, one have implied mapping relation from Gen-Left(k, k−gen) to Gen-Right(k, gen), that is map2(map1(Gen-Left(k, k−gen)))=Gen-Right(k, gen).

Let mapX_{IP} be the mapping function corresponding to idle places where X=1 to 3; mapX_{PT} corresponding to places and transitions; mapX_{R} corresponding to sharing resources; mapX_{HN} corresponding to the holder of the non-sharing resource; mapX_{NR} corresponding to the non-sharing resource, the example shown in FIG. 4 are listed as follows:
map3_{IP}(p₀, p′₀, t₄, t₁, t′₁, t′₄)=map2_{IP}(p₀, p′₀, t₁, t₄, t′4, t′₁)=(p′₀, p₀, t′₁, t′₄, t₄, t₁);
map3_{PT}(p₁, p′₁, t₁, t*₂, t′₂, t′₁)=map2_{PT}(p₃, p′₃, t₄, t₃, t′₃, t′₄)=(p′₃, p₃, t′₄, t*₃, t₃, t₄);
map3_{R}(r₁, t*₂, t₁)=map2_{R}(r₃, t₃, t₄)=(r₃, t*₃, t′₄);
map3_{HN}(p*, t*₂, t₂)=map2_{HN}(p*, t₃, t*₃)=(p*, t*₃, t₃);
map3_{NR}(r′₁, t₂, t*₂)=map2_{NR}(r′₂, t*₃, t₃)=(r′₂, t′₃, t*₃).

Let the states pattern of Gen-Left(k, gen), Gen-Left(k, k−gen), rev(Gen-Left(k, gen)) and the inverted and left and right rotation net of Gen-Right(k, gen) be headed with s_{L}, s_{L}^{k-g}, s_{L}^{rev} and s_{R}, respectively, as shown in FIG. 4. Lemma 1 shows the state pattern relationship between Gen-Right, Gen-Left and Gen-Left(k, k−gen).

Lemma 1.1: Let s₁, . . . , s_{k-gen}, [y], sₖ be the token distribution of resources r₁, . . . , r_{k-gen}, r* . . . , rₖ in Gen-Left(k, k−gen), then s_{L}^{k-g}(s₁, . . . , s_{k-gen}[y], . . . , sₖ), s_{L}^{rev}(sₖ, . . . , [y]s_{gen}, . . . s₁) and s_{R}(−sₖ, . . . , [−y](−s)_{gen} . . . −s₁) are the functional equivalence states and they have the same type of CRSs. Let k=3, gen=2, for a Gen-Left(3, 3−2) as shown in FIG. 4, s_{L}³⁻²(−1 [0], 1, −1) is a reachable state, both s_{L}^{rev}(−1, 1 [0], −1) and s_{R}(1, −1 [0], 1) are also reachable states; s_{L}³⁻²(1 [1], −1, −1) is a deadlock state, then both s_{L}^{rev}(−1, −1 [1], 1) and s_{R}(1, 1 [−1], −1) are also deadlock states.

Corollary 1.1: Gen-Left(k, k−gen), rev(Gen-Left(k, gen)) and Gen-Right(k, gen) all have same closed-form solution (CFS).

Theorem 1.1 shows that Gen-Left(k, k−gen) is a “topological reverse” net of Gen-Left(k, gen). Gen-Left(k, k−gen) can be called a relay reverse net because its CFS can be directly derived from the validated parts of Gen-Left(k, gen) by replacing “gen” with “k−gen”. Applying functional equivalence mapping of Gen-Left(k, k−gen) and Gen-Right, the mirroring, CFS for the Gen-Right can be derived without detailed siphon net structure analysis. Lemma 1 provide the state transformation rule among Gen-Left(k, k−gen), rev(Gen-Left(k, gen)) and Gen-Right(k, gen). The present invention calls this analyzing methodology topological reverse mirroring (TRM).

2. The CFF for Variant Double Deficient k-Th Order System with One Non-Sharing Resource

Let DDk(k, α, β) be Double Deficient k-th order system, where k is the number of sharing resources places M₀(p₀)=α, M₀(p′₀)=β; DDGen-Left(k, α, β, gen) be Gen-Left(k, gen), where M₀(p₀)=α, M₀(p′₀)=β; DDGen-Right(k, α, β, gen) be Gen-right(k, gen), where M₀(p₀)=α, M₀(p′₀)=β, the CFF for Variant Double Deficient k-th order system are shown as followings.

The present invention will use an embedded filtering coefficient (EFC) in front of the CFF as the essential condition for α and β for each type of CRSs as shown in table 1.

1. The EFC for reachable states: the essential condition is (α≥0 and β≥0). One can use min(max(min(α, β, 0)+1, 0), 1)) as embedded filtering coefficient (EFC) to exclude the possibility (α<0 or β<0). For example, (α<0 or β<0)=>max(min(α, β, 0)+1, 0)=0=>min(max(min(α, β, 0)+1, 0), 1))=0, in which case will force the value of whole formula being 0; (α≥0 or β≥0)=>max(min(α, β, 0)+1, 0)≥1=>min(max(min(α, β, 0)+1, 0), 1))=1, in which case the value of CFF is depending on the successive formula.

2. The EFC for live states: the essential condition is (α≥0 and β≥0) but excluding the condition of (α=0 and β=0), under which condition the state is a deadlock state. One can use (min(max(min(α, β, 0)+1, 0), 1)) (min(max(max(α, 0), max(β, 0)), 1)) as the EFC. For example (α=β=0)=>the value of (min(max(max(α, 0), max(β, 0)), 1)) is 0.

3. The EFC for live states: according to the formula Ļ.=Ŗ−F̧, it is embedded in the formula of reachable and live states.

4. The EFC for deadlock states: the essential condition is (α=β=0)∪(α>0 and β>0). One can use 1−(min(max(max(α, 0), max(β, 0)), 1)) for the special condition of (α=β=0); max(min(α, β, 1), 0) as the EFC for the CFF under the condition of (α>0 and β>0).

5. The EFC for ARRS and ARLS: the essential condition is (α≥1 and β≥1). One can use max(min(α, β, 1), 0) as the EFC. For example, (α≤0 or β≤0)=>min(α, β, 1)≤0=>max(min(α, β, 1), 0)=0; otherwise (α≥1 and β≥1)=>min(α, β, 1)=1=>max(min(α, β, 1), 0)=1, in which case the value of CFF is depending on the successive formula.

TABLE 1
The essential conditions and EFC
for α and β of each type of CRSs

| Types of | essential | |
|---|---|---|
| states | condition(s) | EFC |
| Reachable | (α ≥ 0 and β ≥ 0) | min(max(min |
| state | | (α, β, 0) + 1, 0), 1) |
| Live state | (α ≥ 0 and β ≥ 0)/ | (min(max(min |
| | (α = 0 | (α, β, 0) + 1, 0), 1)) × |
| | and β = 0) | (min(max(max |
| | | (α, 0), max(β, 0)), 1)) |
| Forbidden | (α ≥ 0 and β ≥ 0) | embedded in the |
| | | formula of Ŗ − F |
| Deadlock | 1.(α > 0 and β > 0) | 1. Dependent on the |
| | 2.the special | deadlock states pattern. |
| | condition of (α | 2. 1 − (min(max(max |
| | = 0 and β = 0) | (α, 0), max(β, 0)), 1)) |
| ARRS and | (α > 0 and β > 0) | max(min(α, β, 1), 0) |
| ARLS | | |

Theorem 2.1: The total number of live states of a DDk(k, α, β) is ĻGC(k, α, β)=(min(max(min(α, β, 0)+1, 0), 1))(min(max(max(α, 0), max(β, 0)), 1)) (Σ_{I=0 to min(k, α)}C(k, i)+Σ_{i=0 to min(k, β)}C(k, j)−1).

Theorem 2.2: The total number of reachable states of a DDk(k, α, β) is ŖGC(k, α, β)=min(max(min(α, β, 0)+1, 0), 1)(Σ_{j=0 to k}((Σ_{i=0 to min(j, α-1)}C(j, i))(Σ_{i=0 to min(k-j-1, β)}C(k−j−1, i)))+(Σ_{i=0 to min(k, β)}C(k, i))). Corollary 1: 1) The number of forbidden states in a DDk(k, α, β) is FGC(k, α, β)=min(max(min(α, β, 0)+1, 0), 1)(Σ_{j=0 to k}((Σ_{j=0 to min(j, α-1)}C(j, i))(Σ_{i=0 to min(k-j-1, β)}C(k−j−1, i)))+(Σ_{i=0 to min(k, β)}C(k, i)))−(min(max(min(α, β, 0)+1, 0), 1)) (min(max(max(α, 0), max(β, 0)), 1)) (Σ_{i=0 to min(k, α)}C(k, i)+Σ_{j=0 to min(k, β)}C(k, j)−1).

Theorem 2.3: The total number of deadlock states of a DDk(k, α, β) is ĎGC(k, α, β)=1−(min(max(max(α, 0), max(β, 0)), 1))+(min(α, β, 1))(k−1).

Theorem 2.4: The total number of reachable states in a DDGen-Left is ŖGOL(k, α, β, gen)=ŖGC(k, α, β)+ŖGC(k, α−1, β)+(min(α, β, 1))(Σ_{l=1 to gen}(Σ_{u=gen+1 to k}(Σ_{j=0 to min(k-u, β-1)}(ŖGC(l−1, α−1, β−j−1)C(k−u, j))))).

Theorem 2.5: The total number of live states in a DDGen-Left is ĻGOL(k, α, β, gen)=ĻGC(k, α, β)+ĻGC(k, α−1, β)+(min(α, β, 1))(Σ_{l=1 to gen}(Σ_{u=gen+1 to k}((Σ_{i=0 to min(β-1, u-1)}C(u−1, i))))+Σ_{l=1 to gen}(Σ_{u=gen+1 to k}(((Σ_{i=0 to min(β-1, k-u)}C(k−u, i)))).

Theorem 2.6: The total number of deadlock states in a DDGen-Left is ĎGOL(k, α, β, gen)=1−(min(max(max(α, 0), max(β, 0)), 1))+(max(min(α, β, 1), 0))(gen−1)+min(max(α, 0), 1))*min(max(β, 0), 1))(Σ_{i=gen+1 to k-1}(min(max(i−gen−α+1, 0), 1))+_{Σi=1 to gen}(min(max(α−1, 0), 1)*min(max(β−gen+i, 0), 1)+Σ_{i=gen+1 to k-1}(min(max(α+gen−i, 0), 1)*min(max(β, 0), 1))+(min(max(α−1, 0), 1)*min(max(β−1, 0), 1)*(Σ_{i=1 to gen-1}(Σ_{j=gen+1 to k-1}(Σ_{q=1 to min}(β−1, gen−i) min(max(β−q, 0), 1)))).

The formulas are consistent with the reachability analysis using the INA (Integrated Net Analyzer) tool (1992). Extending TRM to DDGen-Left(k, α, β, gen), one can find rev(DDGen-Left(k, α, β, k−gen)=DDGen-Left(k, α, β, gen)), and there is a 1−1 and convertible mapping between the DDGen-Left(k, α, β, k−gen) and the DDGen-Right(k, β, α, gen) such that one can directly derived the CFS for a DDGen-Right by replacing the parameter list (k, α, β, gen) of a DDGen-Left by (k, β, α, k−gen).

Hence, the CFS for a DDGen-Right is shown below:
ŖGOR(k, α, β, gen)=ŖGOL(k, β, α, k−gen);
ĻGOR(k, α, β, gen)=ĻGOL(k, β, α, k−gen);
FGOR(k, α, β, gen)=FGOL(k, β, α, k−gen);
ḐGOR(k, α, β, gen)=ĎGOL(k, β, α, k−gen).

As such, the present invention completes the CFS for a Gen-One with parameters k, α, β, gen and process, where process contains Left and Right two value only.

```
If process = Left then [symbol]
  GO(k, α, β, gen, process) = ŖGOL(k, α, β, gen); [symbol]
  GO(k, α, β, gen, process) = [symbol] GOL(k, α, β, gen);
  FGO(k, α, β, gen, process) = FGOL(k, α, β, gen);
  \check{D}GO(k, α, β, gen, process) = \check{D}GOL(k, α, β, gen).
Else [symbol]
  GO(k, α, β, gen, process) = ŖGOL(k, β, α ,k-gen); [symbol]
  GO(k, α, β, gen, process) = [symbol] GOL(k, β, α, k-gen);
  FGO(k, α, β, gen, process) = FGOL(k, β, α, k-gen);
  \check{D}GO(k, α, β, gen, process) = \check{D}GOL(k, β, α, k-gen).
End if
```

The application for carrying out the present invention will be described in the following paragraphs.

1. The reachability analyzing for systems with non-sharing sub-net; Double Deficient tokens; multi-non-sharing/multi-tokens resources; and multi-processes extended from variant k-th order system without whole net structure analysis.

1.1 Applying to the Construction of CFS for NNS System

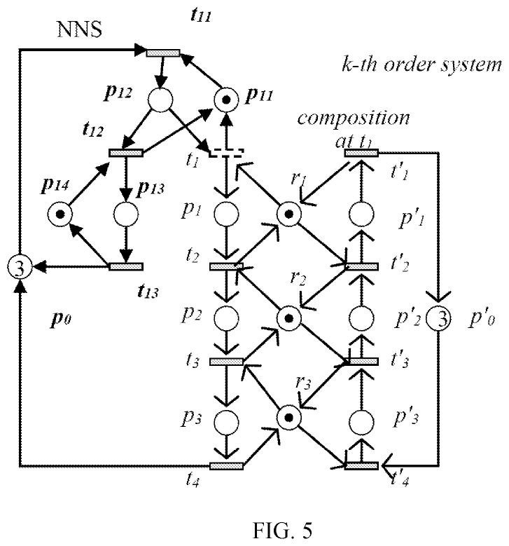

The deficient k-th order system is the essential element of a k-th order system with a non-sharing sub-net (NNS) (as shown in FIG. 5) because the NNS will share some tokens in the idle place of left-hand-side process. Besides, there are so-called livelock states that presently INA cannot detect in such a system. A livelock state occurs when the k-th order-like system contains a deadlock state marking and tokens can only flow in the left process NNS. An example is that p₁, p′₂ and p′₃ contain one token, respectively, which is a deadlock state (1 −1 −1); and the sub-state in the NNS will be always in live states due to no empty siphon.

The total number of reachable states in deficient k-th order system (Def (k, q)) (Chao & Yu, 2017) is RD (k, q)=R(k)−Σ_{l=q+1 to k}(Σ_{i=0 to l-q-1}C(1 −1, 1 −1−i))(2^{k-1}), where q is the number of tokens in the idle place of the left-hand-side process.

The total number of reachable states in Deficient Gen-Left k-th order system (Def-Gen-Left(k, q, gen)) (Yu, 2016 b) is RDG (k, q, gen)=RD(k, q)+RD(k, q−1)+Σ_{i=1 to gen}(Σ_{j=gen+1 to k}RD(i−1, q−1) (2^{k-j})), where gen is the location of a non-sharing resource in the Def-Gen-Left(k, q, gen).

Based on the formulas listed above, one can derive CFF of the number of reachable state for k-th order system with a NNS and a non-sharing resource in left-hand-side process, NNS-Gen-Left k-th order system (NNS-Left(k, m, gen)), as shown below.

RNNS−Gen (k, m, gen)=Σ_{l=0 to m}((|f(l)|)RDG (k, k−1, gen)), where m is the maximum token number that can flow into NNS and the limitation of m is m<k; f(l) is a measurable state function of NNS and l is the number of tokens flowing into NNS, such that |f(l)| can map to a non-ambiguous number of different states combination under the current information of l in NNS.

According to TRM one can easily derive CFS for the rev(NNS-Left(k, m, gen)) which is the fundamental model of merging two different manufacturing processes. The topological reverse net of Def-Gen-Left(k, q, gen) is Def-Gen-Left(k, q, k−gen) and the mirroring is the net of Def-Gen-Left(k, q, k−gen) itself which is a reversible one-to-one function. Hence, one can derive CFF of reachable states for rev(NNS-Left(k, m, gen)) being

Rrev(NNS−Gen)(k, m, k−gen)=Σ_{l=0 to m}((|f(l)|)RDG(k, k−1, k−gen)) without whole net structure analysis.

1.2 Reachability Analysis for Double Deficient k-th Order System with One Non-Sharing Resource

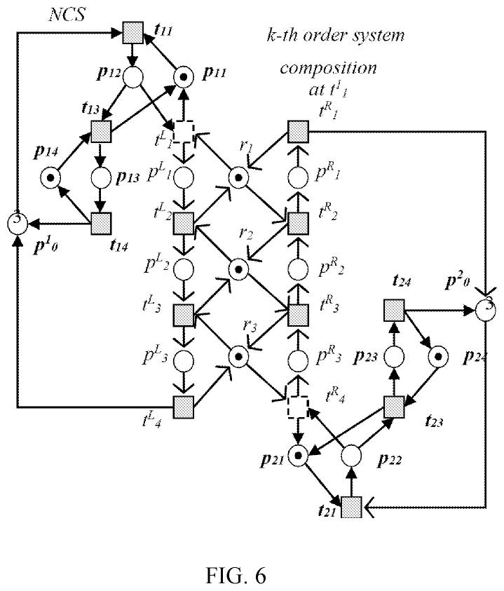

FIG. 6 shows a double-NNS system. When both NNSs contain tokens (excluding initial tokens places), the k-th order system will become a Double Deficient k-th order system.

Let ŖGC(k, α, β)=min(max(min(α, β, 0)+1, 0), 1)(Σ_{j=0 to k}((Σ_{i=0 to min(j, α-1)}C(j, i))(Σ_{i=0 to min(k-j-1, β)}C(k−j−1, i)))+(Σ_{i=0 to min(k, β)}C(k, i))) be the number of reachable states of Double Deficient k-th order system with α tokens in p₀; β tokens in p′₀, the number of reachable states of Double Deficient k-th order system with a non-sharing resource at lon location of the left process is ŖGOL(k, α, β, lon)=ŖGC(k, α, β)+ŖGC(k, α−1, β)+(min(α, β, 1))(Σ_{l=1 to lon}(Σ_{u=lon+1 to k}(Σ_{j=0 to min(k-u, β-1)}(ŖGC(l−1, α−1, β−j−1)C(k−u, j))))).

Applying TRM, one can easily derive the number of reachable states of double deficient k-th order system with a non-sharing resource at lon location of the right process is ŖGOL(k, β, α, k−lon).

1.3 Reachability Analysis for Multi-Non-Sharing Resources Systems

For a subnet containing two non-sharing resource systems, s=(x₁ . . . xᵢ[y] . . . xj[z] . . . xₖ), where xₘ=1, 0, −1; y=0, 1; z=0, −1, with a left side non-sharing resource after i location, xᵢ[y], and a right side one after j location, xⱼ[z]. According to the “additional restricted reachable (resp. live) States derived from non-reachable (non-live) states of the equivalent (defined in Definition 6) caused by the non-sharing resource” (ARRS)(resp. ARLS) information of Gen-Right and Gen-Left, one can intuitively exclude the states patterns that do not belong to the ARRS pattern of s:(x₁ . . . −1 xᵢ[y] . . . 1 1 . . . xⱼ[z] . . . xₖ) and (x₁ . . . xᵢ[y] . . . −1 −1 . . . xⱼ[z] . . . 1 xₖ), since (−1 xᵢ[y] . . . 1 1) is not a reachable sub-state of the Gen-Left, nor is (−1 −1 . . . xⱼ[z] . . . 1 xₖ) for Gen-Right. Hence the ARRS information of Gen-One can be used for analyzing the reachability and constructing the CFF for k-th order system with multi-non-sharing resources. The effort required for the construction of CFF can be reduced by the TRM. When one construct CFF, fs(k, Li, Rj) for s, one can also derive CFF fs(k, R(k−i), L(k−j)) for a right side non-sharing resource xᵢ[y] and a left side one xⱼ[z] (y=0, 1; z=0 −1) just according to the TRM.

1.4 Reachability Analysis for Multi-Tokens Resources Systems

In variant k-th order system with sharing resources containing multi-tokens, there is a similar ARRS states pattern because under the condition of multi-tokens in a sharing resource the left or right process can wait in this sharing resource rm for the other process's work flow. To construct CFS for such a net structure, after deriving CFF f(k, om, gen) of CRSs with the tokens number om of rm resource being in the left process pgen, one can immediately derive the part of the same number of tokens in the right process p′gen, f(k, om, k−gen−1) according to the TRM methodology.

1.5 Reachability Analysis for Multi-Processes Systems

FIG. 6 shows k_{1(μ-1)}(1⁺, 1)-th order system is the reverse net of k_{1(μ-1)}(1⁺, k−1)-th order system and both k_{1(μ-1)}(1⁺, k−1) and k_{(μ-1)1}(1−, 1) have the same net structure. Hence the CFF for _{k(μ-1)1}(1⁻, 1) can be directly derived being the validated CFF for k₁₍ᵤ₋₁₎(1⁺, k−1). Extending to the kᵢⱼG-th order systems, where i≥1 and j≥1, one can find kᵢⱼ (j⁺, k−gen) and kⱼᵢ(j⁻, gen) are the same topological net structures where 1≤j≤i. Based on the closed-form solution of kᵢⱼ(j⁺, gen) and applying the TRM concept, one can derive the closed-form solution for a kⱼᵢ(j⁻, gen) being the solution of kᵢⱼ(j⁺, k−gen).

2. Directly Deriving the CFF for PNs Extended from Variant k-Th Order System without Whole Net Structure Analysis.

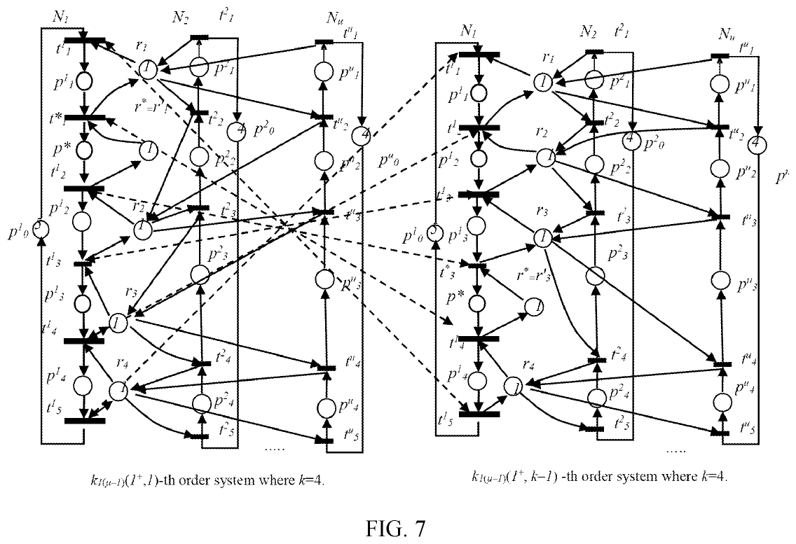

With validated CFF for kᵢⱼ(j⁺, gen), the CFF for kⱼᵢ(j⁻, gen) can be derived according to the mapping relationship map2(map1(kᵢⱼ(j⁺, k−gen)))=map2(rev(kᵢⱼ(j⁺, gen)))=kⱼᵢ(j⁻, gen) as shown in Theorem 1.1, FIG. 4 and FIG. 7 being the CFF for kᵢⱼ(j⁺, k−gen) by replacing the parameter gen with k−gen in CFF for kᵢⱼ(j⁺, gen). Here the parameter gen can be the location of non-sharing resource or sharing resource containing multi-tokens. The validated cases include the CFF for DDGen-Right(k, α, β, gen) is the CFF for DDGen-Left(k, α, β, k−gen) and CFF for k_{(μ-1)1}(1⁻, 1) can be directly derived being the validated CFF for k_{1(μ-1)}(1⁺, k−1) (Chao and Yu, 2016) without whole net structure analysis.

3. Realize the DTH Deadlock Avoiding Function

A simple deadlock avoiding function algorithm EnableState((x_{C}, x_{N})) (Yu, 2016) is shown below, where x_{C} is the single token distribution of the current state to be changed to the single token distribution x_{N} of the next state.

Let Nk be a k-th order system that is the equivalent of a Variant k-th order system N, sub-stateₜ(m, n) be a t-th reachable sub-state (xₘ . . . xₙ) so that the current state of N can be composed by (sub-state₁ . . . sub-stateₜ . . . sub-stateₑ), where 1≤e≤int(k/2)+1, URt be or will be the only one unmarked siphon (rᵢ-rⱼ)-region of Nk in sub-stateₜ where it contains a zero or null sub-state (0ᵢ₊₁ . . . 0ⱼ₋₁), and sₜ be the possible unmarked minimal siphon (denoted as UMS) region derived from URt (the exception condition is that the sub-stateₜ is live or sub-stateₜ contains an ARRS due to NSR).

The function Search(x₁) returns the sub-stateₜ containing the single state x1;
MinProcess(sub-stateₜ) returns the process with the minmal number of operation places containing a token;
   Deallocate(sub-stateₜ, DTH) will deallocate all of DTH in sub-stateₜ;
   Split(sub-stateₜ) will Deallocate(sub-stateₜ, DTH) and split the sub-stateₜ into sub-stateₜ₋ and sub-stateₜ₊ at sₜ while sₜ is a non-reachable marking in Nk;
   Merge(sub-stateₜ(mₜ, nₜ) sub-stateₜ₊₁(mₜ₊₁, nₜ₊₁)) generates the new sub-state′ₜ(mₜ, nₜ₊₁);
   AllocateDTH(sub-stateₜ, Pᵢ) will allocate a DTH according to max(DDGen-Left(k, α, β, gen) or DDGen-Right(k, α, β, gen)) of URt in process Pi where gen is the possible location of DTH;
   Protect(sₜ) (resp. Unprotect(sₜ)) protects (resp. unprotects) sₜ from the traps holding the token due to the work flow of other siphons;
   Place(x_{C}) returns the place containing the token in a single state x_{C}; isProtected(sₜ) returns the Boolean value as true when sₜ is protected; and
   ProcessOf(Place(x_{C})) will return the process Pᵢ of Place(x_{C}).

```
EnableState((x_{C}, x_{N})) {
  1 sub-stateₜ=Search(x_{C}); sub-state't=Search(x_{N});
  2 if (sub-stateₜ≠sub-state'ₜ) then {Merge(sub-stateₜ, sub-state'ₜ); }
  3 if (x_{C} is not in URₜ) then {return SUCC;}
  4 if (URₜ contains no NSR or DTH) then {AllocateDTH(sub-stateₜ,
MinProcess(sub-stateₜ));}
  5 if (isProtected(sₜ) and Place(x_{C}) in trap of sₜ) {return SUCC}
  6 if (isProtected(sₜ) and Place(x_{C}) in H(DTH) and reachable to x_{C}) {
    if (no other H(DTH) contains token in URₜ) then {
    Unprotected(sₜ); Split(sub-stateₜ);
    Merge(sub-stateₜ₋₁, sub-stateₜ);
    Merge(sub-stateₜ₊,sub-stateₜ₊₁); }
    return SUCC; }
  7 if (Place(x_{N}) in H(DTH) and URₜ is UMS and not isProtected(sₜ) )
{Protect(sₜ); return WAITING; }
  8 if (Place(x_{N}) not in H(DTH) and URₜ is UMS and not
  isProtected(sₜ)) { Protect(sₜ); Deallocate(sₜ, DTH); Allocate_DTH(sₜ,
  ProcessOf(x_{C})); return WAITING; }
  9 if (Place(x_{C}) not in sₜ and isProtected(sₜ)) {return HOLDING; } }
When the return value is SUCC then the state can progress to x_{N} from
xC; WAITING, waiting in DTH of xC ; and HOLDING waiting in xC
until Unprotected(st).
```

The additional advantage of DTH deadlock avoiding function is that one can dynamically encapsulate such sub-state as an independent module of whole system because no extra allocated sharing resource is needed for deadlock policy.

Conclusively, CFF for Petri nets realize the possibility of providing real-time reachability information from EXPSPACE-hard problem. Some concepts of large system control applications based on current state are proposed. However the traditional whole-net structure analyzing method limits presently the CFF only the variant k-th order systems be derived such that limits new applications proposed and the applications be applied to more complicated modeling Petri nets. To solve the problem, the present invention reports a new efficient knowledge-based methodology “topological reverse mirroring” (TRM) to enhance the theoretical framework for constructing CFS for PNs without complicated whole-net siphon analysis, and the CFF for Variant Double Deficient k-th order system as the basic system to extend analyzing reachability and deriving the CFF for more complicated Petri Nets.

An embodiment is given in the following to better understand the present invention.

Suppose a flexible manufacturing sub-system containing two manufacturing processes (N₁ and N₂ in FIG. 1) sharing a conveyor system with a series of redirectable components (rᵢ, i=1 to k, called sharing resources), one can apply k-th order system to model such sub-system as mapping tags shown. The benefit of such sub-system is high utilization of processes and sharing resources during manufacturing on demand. However, when two processes are launched simultaneously, deadlock will occur during both rᵢ and rᵢ₊₁ are used to deliver each object forward to face-to-face opposite direction.

In case of no additional sharing resource allowed due to limited space and only the temporary storage of each place (pᵢ and p′ᵢ) of both processes can avoid deadlock, one can apply deadlock ratio of current state as the indicator to launch a deadlock avoidance policy. Yu (2016a) proposed a deadlock thread-holder (DTH, a dummy non-sharing waiting resource) avoidance deadlock policy based on which location DTH allocated will increase maximum reachability. Here, DTH is the temporary storage of a place for waiting the other working process. Furthermore one can encapsulate such sub-system as an independent module of whole system because no extra allocated sharing resource is needed for deadlock policy.

Extending the sub-system containing two sub-nets in both processes as shown FIG. 6, the sub-system can manufacture four different products in same time. Suppose the whole system includes multiple such independent sub-systems. One of to be solved problems is what kind of product of which sub-system to be manufactured will be more efficient in utilization of processes and sharing resources based on current state. Yu (2017) showed that lower modified deficient reachability ratio (DRO)(the number of reachable states under deficient initial tokens/the number of reachable states) has better margin effect of reachability, one can set up a dynamic initial token allocation mechanism according to which system has the lowest DRO value.

When k is very large, based on CFF for PN, such as ŖGOL(k, α, β, lon) formula, the values of deadlock ratio, the location of DTH and the DRO of current state can be easily estimated real-time to realize the total solution for manufacturing mentioned above. However, due to NP-complete problem, presently the values cannot be derived real-time based on traditional reachability analysis method.

CFF for Petri nets realizes the possibility of providing real-time reachability information from EXPSPACE-hard problem. Some concepts of large system control applications based on current state are proposed. However the traditional whole-net structure analyzing method limits presently the CFF only the variant k-th order systems be derived such that limits new applications proposed and the applications be applied to more complicated modeling Petri nets.

To solve the problem, the present invention reports a new efficient knowledge-based methodology “topological reverse mirroring” (TRM) to enhance the theoretical framework for constructing CFS for PNs without complicated whole-net siphon analysis, and the CFF for Variant Double Deficient k-th order system as the basic system to extend analyzing reachability and deriving the CFF for more complicated Petri Nets.

Unless otherwise defined, all terms (including technical and scientific terms) used herein have the same meaning as commonly understood by one of ordinary skill in the art to which this disclosure belongs. It will be further understood that terms; such as those defined in commonly used dictionaries, should be interpreted as having a meaning that is consistent with their meaning in the context of the relevant art and the present disclosure, and will not be interpreted in an idealized or overly formal sense unless expressly so defined herein.

1. A method for analyzing reachability of a Petri net (PN) and deriving the control-related state of the PN extended from the kth variant closed-form formula (CFF) system for numbers, the method comprising:
by proving that the first system Gen-Right(k, gen) and the second system Gen_Left(k, k−gen) are topological inverse networks of Gen-Left(k, gen), the first system and the second system An invertible one-to-one mapping between;
wherein the first series Gen-Right(k, gen) and Gen-Left(k, k−gen) have the same closed-form formula, and by putting Gen-Left(k, gen) in the verified closed-form formula The parameter gen can be obtained by replacing it with k−gen, and its corresponding reachability state can be directly obtained through a reversible one-to-one mapping.

2. The method for analyzing reachability of a Petri net as claim 1, wherein the method is based on knowledge-based use of the verified network accessibility and closure solution information to change parameter values such as itineraries, non-shared resources and multi-scepter shared resource locations, and directly obtain the new network, the network architecture has a reversible one-to-one mapping of the reachability and closure solution information of the new network architecture, the method is referred to here as Topological Reverse Mirroring (TRM).

3. The method for analyzing reachability of a Petri net as claim 2, wherein the topological inverse mirror system is used to analyze reachability and derive a closed-form formula to control the number of control-related states.

4. The method for analyzing reachability of a Petri net as claim 3, wherein the control-related states are reachable, active, prohibited, deadlocked, livelocked, and unreachable.

5. The method for analyzing reachability of a Petri net as claim 1, wherein the method further includes providing the CFF of the number of CRSs of the double-deficient k-order system of non-shared resources.

6. The method for analyzing reachability of a Petri net as claim 5, wherein the method further includes using embedded filter coefficients (EFC) in front of the CFF as a necessary condition for each of the α and β of the CRS.

7. The method for analyzing reachability of a Petri net as claim 5, wherein the necessary conditions for the EFC of the reachable state are α≥0 and β≥0;
where min(max(min(α, β, 0)+1, 0), 1)) is used as the embedded filter coefficient (EFC) to exclude possibilities (α<0 or β<0).

8. The method for analyzing reachability of a Petri net as claim 5, wherein the necessary conditions for the EFC of the active state are α≥0 and β≥0, but excluding the conditions of α=0 and β=0;
where, using (min(max(min(α, β, 0)+1, 0), 1)) (min(max(max(α, 0), max(β, 0)), 1)) as EFC.

9. The method for analyzing reachability of a Petri net as claim 5, wherein the basic condition of the EFC of the dead state is (α=β=0) union (α>0 and β>0);
where, use 1−(min(max(max(α, 0), max(β, 0)), 1)); max(min(α, β, 1), 0) as (α>0 and β>0) EFC of CFF under condition.

10. The method for analyzing reachability of a Petri net as claim 1, wherein the CFF of the number of CRSs of the non-shared resource double-deficient k-order system is used as the basic model for deriving the CFF of more complex PNs by applying the TRM, and provides decision-making based on the current state of the real-time reachability information system control application.
